(19) United States
(12) Patent Application Publication
(10) Pub. No.: US 2007/0259542 A1
(43) Pub. Date: Nov. 8, 2007

(54) Electronic Device Capable of Detecting a Category of an External Device and Related Method

(76) Inventors: Ming-Liang Yang, Hua-Lien Hsien (TW); KUEI-PIN TSAI, Hsin-Chu Hsien (TW); Ju-Chieh Lin, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/743,144

(22) Filed: May 1, 2007

(30) Foreign Application Priority Data
May 2, 2006 (TW) 095115622

(51) Int. Cl. H05K 1/00

(52) U.S. Cl. 439/70

(57) ABSTRACT

A set of electronic frames capable of detecting an external device includes a main frame and an external frame. The main frame includes an R-C circuit with a detecting pin, a resistor coupled to the detecting pin, and a voltage comparator for comparing the potential at the detecting pin and a reference potential. The external frame includes a connecting port coupled to the R-C circuit of the main frame. The connecting port includes an identifying pin coupled to the detecting pin, and an R-C circuit coupled to the identifying pin. The voltage comparator is utilized for comparing the potential of the first end of the resistor of the main frame and the reference potential after each predetermined time gap

### BACKGROUND OF THE INVENTION

1. Field of the Invention

The present invention relates an electronic device capable of detecting a type of an external device and related method, and more particularly, to an electronic device capable of detecting the type of the external device and related method by comparing a potential of a detecting pin and a reference potential.

2. Description of the Prior Art

One of the many trends apparent in current digital electronic devices is the move towards producing a lighter and a more compact device. Predominantly, the only other modern day requirement of electronic device is the need to include as many functions as possible, of course, while maintaining said light and compact device design. In order to meet such disparate demands, the digital electronic device available in the consumer market today can be connected to various external devices. These external devices either come bundled with the digital electronic device or are otherwise available as additional purchases/add-ons. The external devices function to expand the peripheral abilities of the digital electronic device. For example, a mobile phone can be connected to an external camera module, or a personal digital assistance (PDA) can be connected to a data transmission module to output data, or any type of electronic device can connect to an external charger for charging. As the digital electronic device is limited by size, and at the same time other external functions will not be utilized, therefore the conventional electronic device usually connects to an external device through an external port, thus the digital electronic device requires a function that can detect the type of the external device, connected to said external port, so as to accurately utilize the external device to fully expand and utilize its peripheral abilities.

Please refer to FIG. 1. FIG. 1 illustrates a conventional set of electronic frames. A main frame 110 includes an external port 112. The external port 112 needs to include peripheral communication protocols (such as an 8080 8 Bit interface, an RS-232 interface, or a USB interface), the external port 112 also needs to include a detecting pin 114. As illustrated in FIG. 1, an end of the detecting pin 114 of the main frame is connected to an analogue voltameter 118 capable of detecting voltage, and is connected to a reference voltage Vref through a reference resistor 116. When the conventional main frame 110 is connected to an external device 120 through the external port 112, the detecting pin 112 of the main frame 110 will be connecting to an identifying pin 124 of a connecting port 122 of the external device 120, where the identifying pin 124 is further coupled to an identifying resistor 126. When the conventional main frame 110 is connected to the external device 120, the analogue voltameter 118 immediately detects a reference voltage Vref at voltage divider V_test1 of the detecting pin 114, hence, a resistance value of the identifying resistor 126 of the external device 120 can be found so that it is thereafter possible for the type of the external device 120 to be identified. For example, in the prior art an identifying resistance value of an external camera module of a mobile phone can be set as R1, an identifying resistance value of an external charger can be set as R2, and an identifying resistance value of an external earphone can be set to R3. If a reference resistance value of a conventional mobile phone is set to R4, then when an analogue voltameter of the mobile phone detects (R3/(R3+R4))×Vref at voltage divider V_test1 of the detecting pin, then we can know that the external port 112 of the mobile phone is currently connected to an earphone.

The conventional digital electronic device can utilize the above-mentioned mechanism to identify the type of the external device through the analogue voltmeter method. However, in the conventional mechanism, the digital electronic device is required to utilize an analogue pin as the detecting pin of the external port, and the digital electronic device is required to install an analogue voltameter for detecting the voltage value of the detecting pin. Hence, the cost of the digital electronic device will inevitably increase when support for the conventional mechanism to identify the type of the external device is included. As a result, the conventional mechanism will cause limitation in the production line.

### SUMMARY OF THE INVENTION

The claimed invention discloses a set of electronic frames comprising a main frame and an external frame. The main frame comprises an external port comprising a detecting pin; a resistor comprising a first end coupled to the detecting pin; and a voltage comparator for comparing potential of the first end of the resistor and a reference potential. The external frame comprises a connecting port coupled to the external port of the main frame, the connecting port comprising an identifying pin, the identifying pin coupled to the detecting pin; and an R-C circuit coupled to the identifying pin. The voltage comparator is utilized for comparing the potential of the first end of the resistor of the main frame and the reference potential after each predetermined time gap.

The claimed invention further discloses an electronic device capable of detecting external devices. The electronic device comprises an external port for connecting to an external device, the external port comprises a detecting pin; a resistor comprises a first end coupled to the detecting pin; and a voltage comparator for comparing potential of the first end of the resistor and a reference potential.

The claimed invention further discloses a method of an electronic device in detecting external devices. The method comprises comparing a potential of a detecting pin of an external port of an electronic device and a reference potential; and determining the type of the external device connected to the electronic device according to a comparison result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a conventional set of electronic frames according to the prior art.

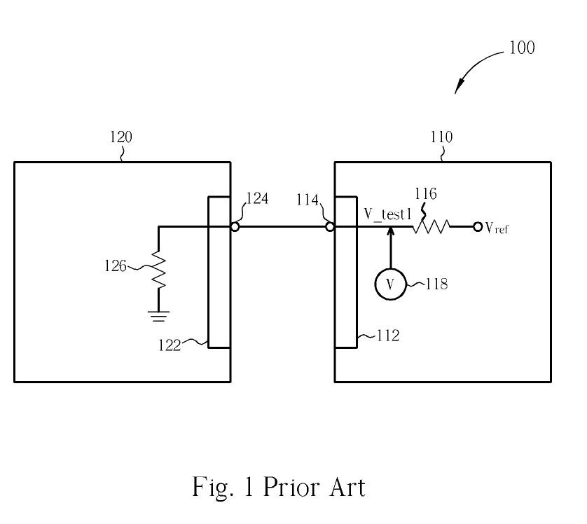

FIG. 2 illustrates a set of digital electronic devices according to an embodiment of the present invention.

FIG. 3 illustrates a diagram of the end potential V_test2 of the detecting pin of the main frame of FIG. 2 according to an embodiment of the present invention.

FIG. 4 illustrates a flowchart of an electronic device detecting the type of an external device according to an embodiment of the present invention.

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

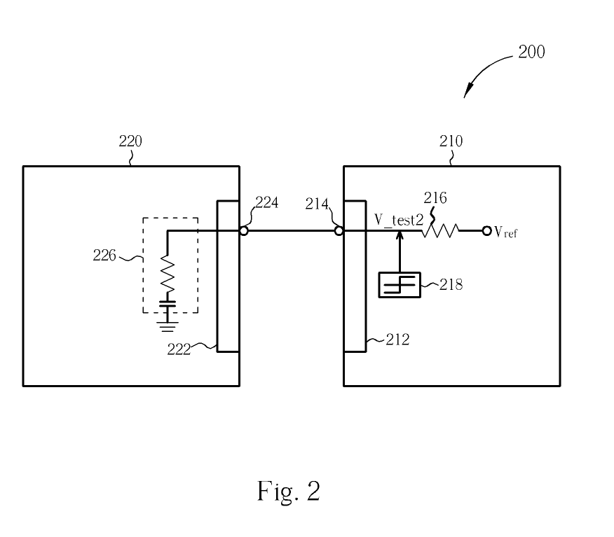

Please refer to FIG. 2. FIG. 2 illustrates a set of digital electronic devices 200 according to the present invention. A digital electronic main frame 210 includes an external port 212, and the external port 212 includes a detecting pin 214. As illustrated in FIG. 2, an end of the detecting pin 214 of the main frame 210 is connected to a voltage comparator 218, and is also connected to a reference voltage Vref through a reference resistor 216. When the main frame 210 is connected to an external device 220 through the external port 212, the detecting pin 212 of the main frame 210 will be connected to an identifying pin 224 of a connecting port 222 of the external device 220. The identifying pin 224 of the external device 220 is further coupled to an R-C circuit 226. When the main frame 210 is connected to the external device 220, the voltage comparator 210 immediately compares a reference potential V_th and potential V_test2 of the end of the detecting pin 214 so as to obtain characteristic of the R-C circuit 226 of the external device 220 in order to identify the type of the external device 220.

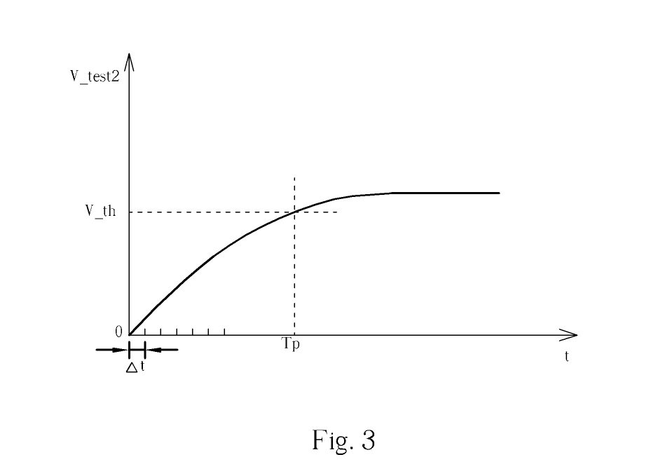

Please refer to FIG. 3. FIG. 3 illustrates a diagram of the end potential V_test2 of the detecting pin 214 of the main frame of FIG. 2. The present invention utilizes a digital voltage comparator 218 instead of a conventional analogue voltameter for comparing a reference potential V_th and the end potential V_test2 of the detecting pin 214. For example, the voltage comparator 218 of the present invention can be designed to compare the reference potential V_th and the end voltage V_test 2 of the detecting pin 214 after each predetermined time gap Δt. As illustrated in FIG. 3, at time point Tp, a comparison result of the voltage comparator 218 is the end potential V_test2 of the detecting pin 214 exceeding the reference potential V_th. As an ascending curve of the end potential V_test2 of the detecting pin 214 is related to characteristics of the identifying R-C circuit of the external device, thus when the end potential V_test2 of the detecting pin 214 exceeds the reference potential V_th of the time point, the type of the external device can be known through the characteristics of the identifying R-C circuit of the connecting external device.

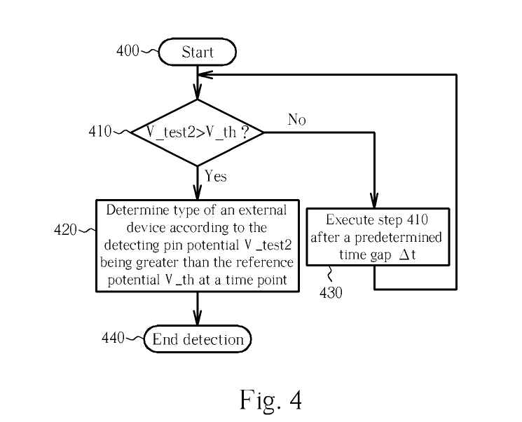

Please refer to FIG. 4. FIG. 4 illustrates a flowchart of an electronic device detecting type of external device according to the present invention.

Step 400: start;

Step 410: compare potential V_test2 of a detecting pin of an external port of an electronic device and a reference potential V_th; if the detecting pin potential V_test2 is greater than the reference potential V_th, then execute step 420; if not execute step 430;

Step 420: determine the type of the external device according to the detecting pin potential V_test2 being greater than the reference potential V_th at a time point;

Step 430: execute step 410 after a predetermined time gap Δt;

Step 440: end detection.

In comparison to the prior art, the digital electronic device of the present invention does not require that an expensive analogue voltameter be utilized, whereas a digital voltage comparator is utilized to compare voltage of the detecting pin with a reference potential in an interval time gap, thus the R-C circuit characteristics of the external device can be detected so as to identify the type of the external device connected to the main frame through the external port. Software in the digital electronic device can obtain different time points Tp (detecting pin voltage exceeding reference potential of time point) corresponding to the type of a peripheral device through a checklist method. As for the main frame, the main frame utilizes the detecting method of the present invention, the hardware portion can be independent to the changes of the peripheral devices, and the software of the detecting mechanism can be easily understood as illustrated in FIG. 4.

In conclusion, the present invention provides an electronic device capable of detecting a type of an external device and related method to successfully replace the analogue voltameter with a digital voltage comparator, and to realize the requirement of identifying different peripherals of a modern electronic device by utilizing a simpler method and lower cost that the conventional prior art devices and methods.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A set of electronic frames comprising:
a main frame comprising:
an external port comprising a detecting pin;
a resistor comprising a first end coupled to the detecting pin; and
a voltage comparator for comparing a potential of the first end of the resistor and a reference potential; and
an external frame comprising:
a connecting port coupled to the external port of the main frame, the connecting port comprising an identifying pin, the identifying pin coupled to the detecting pin; and
an R-C circuit coupled to the identifying pin;
wherein the voltage comparator is utilized for comparing the potential of the first end of the resistor of the main frame and the reference potential after each predetermined time gap.

2. The set of electronic frames of claim 1 wherein the voltage comparator is utilized for comparing the potential of the first end of the resistor of the main frame and the reference potential after each determined time gap when the potential of the first end of the resistor of the main frame is less than the reference potential.

3. The set of electronic frames of claim 1 wherein the voltage comparator determines a type of the external device according to a comparison result of the voltage comparator.

4. An electronic device capable of detecting external devices, the electronic device comprising:
an external port for connecting an external device, the external port comprising a detecting pin;
a resistor comprising a first end coupled to the detecting pin; and
a voltage comparator for comparing a potential of the first end of the resistor and a reference potential.

5. The electronic device of claim 4 wherein the voltage comparator is utilized for comparing the potential of the first end of the resistor of the main frame and the reference potential after each predetermined time gap.

6. The electronic device of claim 5 wherein the voltage comparator is utilized for comparing the potential of the first end of the resistor of the main frame and the reference potential after each determined time gap when the potential of the first end of the resistor of the main frame is less than the reference potential.

7. The electronic device of claim 4 wherein the voltage comparator determines a type of the external device according to a comparison result of the voltage comparator.

8. A method of an electronic device in detecting external devices, the method comprising:
comparing a potential of a detecting pin of an external port of an electronic device and a reference potential; and
determining a type of the external device according to a comparison result.

9. The method of claim 8 wherein the step of comparing the potential of the detecting pin of the external port of the electronic device and the reference potential is executed after each predetermined time.

10. The method of claim 9 wherein the step of comparing the potential of the detecting pin of the external port of the electronic device and the reference potential after each predetermined time is executed when the potential of the detecting pin of the external port of the electronic device is less than the reference potential.

11. The method of claim 9 wherein the step of determining the type of the external device according to the comparison result determines the type of the external device according to the potential of the detecting pin of the external port of the electronic device when exceeding the reference potential.
